(19) United States
(12) Patent Application Publication
(10) Pub. No.: US 2022/0247058 A1
(43) Pub. Date: Aug. 4, 2022

(54) HIGH POWERED RF PART FOR IMPROVED MANUFACTURABILITY

(71) Applicant: TTM TECHNOLOGIES INC., Santa Ana, CA (US)

(72) Inventors: Michael Len, Skaneateles, NY (US); Hans Peter Ostergaard, Viborg (DK)

(21) Appl. No.: 17/725,371

(22) Filed: Apr. 20, 2022

Related U.S. Application Data
(63) Continuation-in-part of application No. 17/492,389, filed on Oct. 1, 2021.
Application No. 17/492,389 is a continuation of application No. 15/486,361, filed on Apr. 13, 2017, now Pat. No. 11,158,920.
(60) Provisional application No. 62/327,839, filed on Apr. 26, 2016.
(60) Provisional application No. 62/338,281, filed on May 18, 2016.

(51) Int. Cl. H01P 1/30; H01P 5/18; H05K 1/02

(52) U.S. Cl. CPC H01P 1/30; H01P 5/187; H05K 1/0306; H05K 1/0243; H05K 1/0204; H05K 1/0203

(57) ABSTRACT

An electrical component, such as an RF device or thermal bridge, for use with a printed circuit board. The component may include a first dielectric layer having a top and a bottom, and a first conductive trace positioned on the bottom of the first dielectric layer. The component may also include a first ground layer positioned on the bottom of the first dielectric layer and spaced apart from the first conductive trace and a first solder layer connecting the first conductive trace to a second conductive trace of the printed circuit board and extending the full length of the first conductive trace. The component may also include a third conductive trace over the top of the first dielectric layer. The component may also include a pad under the first dielectric layer. The pad is soldered to a signal contact region of the printed circuit board. The third conductive trace is coupled to signal outputs formed by the signal contact region of the printed circuit board through a first via. The component may also include a second solder layer connecting the first ground layer of the component to a second ground layer positioned on the printed circuit board.

### CROSS-REFERENCE TO RELATED APPLICATIONS

The present application is a continuation-in-part of U.S. patent application Ser. No. 17/492,389, entitled “HIGH POWERED RF PART FOR IMPROVED MANUFACTURABILITY,” filed Oct. 1, 2021, which is a continuation of U.S. patent application Ser. No. 15/486,361, entitled “HIGH POWERED RF PART FOR IMPROVED MANUFACTURABILITY,” filed Apr. 13, 2017, which issued as U.S. Pat. No. 11,158,920 on Oct. 26, 2021, which claims priority to U.S. Provisional Application No. 62/327,839, filed Apr. 26, 2016, and U.S. Provisional Application No. 62/338,281, filed May 18, 2016, each of which is incorporated herein by reference in its entirety.

### BACKGROUND OF THE INVENTION

### Field of the Invention

The present invention relates generally to electrical components and, more particularly, to a coupler having improved power handling for RF and thermal bridge applications.

### Description of the Related Art

The power handling of a given RF device is limited by its heat dissipation capabilities. Examples of typical RF devices include microstrip transmission lines, stripline transmission lines, and broadside stripline couplers disposed on microstrip printed circuit boards. The heat dissipation characteristics of a given design depend on its configuration and the type of dielectric materials employed therein. If the thermal energy generated by an RF device is dissipated over a relatively small surface area, the heat will build up over time, become problematic and thus limit the power handling capabilities of the device.

The thermal energy conducted through a device or assembly can be described by the thermal resistance (Rₜₕ). Moreover, each element or component (e.g. conductor or dielectric layer) that the heat traverses or conducts through is characterized by a thermal resistance. The power handling of a given RF device is limited by its heat dissipation capabilities, and the power handling of the assembly is a function of the thermal resistance (Rₜₕ), ambient or mounting temperature, a maximum operating temperature, and the dissipated power (in the conductor):

$$Dissipated power = ( {P}_{in} ) ( 1 - {10}^{- ( IL \text{/} 10 )} ) ,$$

where Pᵢₙ is the input power [W] and IL is the insertion Loss [dB];

$${R}_{th} = D \text{/} ( k * A ) ,$$

where k is the Thermal Conductivity [W/mK] of the material that the heat is passing through, D is the Distance [m] of heat flow, and A is the cross-sectional area of the heat flow [m²]. The maximum operating temperature is defined as the maximum temperature at which a material may be subjected to, that will not cause degradation of the material.

Thus, there is a need for an approach that can reduce the number of thermal resistance elements for a given assembly, thereby improving overall thermal performance and heat dissipation characteristics.

### BRIEF SUMMARY OF THE INVENTION

The present invention provides a system that reduces the number of thermal resistance elements when coupled to a printed circuit board and thus provides for improved thermal performance.

In one aspect, an electrical component is provided for a printed circuit board. The electrical component may include a first dielectric layer having a top and a bottom, and a first conductive trace positioned on the bottom of the first dielectric layer. The electrical component may also include a first ground layer positioned on the bottom of the first dielectric layer and spaced apart from the first conductive trace, and a first solder layer connecting the first conductive trace to a second conductive trace of the printed circuit board and extending the full length of the first conductive trace. The electrical component may also include a third conductive trace over the top of the first dielectric layer. The electrical component may also include a pad under the first dielectric layer. The pad is soldered to a signal contact region of the printed circuit board. The third conductive trace is coupled to signal outputs formed by the signal contact region of the printed circuit board through a first via. The electrical component may also include a second solder layer connecting the first ground layer of the component to a second ground layer positioned on the printed circuit board.

In another aspect, an electrical component is provided for a printed circuit board. The electrical component may include a first dielectric layer having a top and a bottom, and a first conductive trace positioned on the bottom of the first dielectric layer. The electrical component may also include a first ground layer positioned on the bottom of the first dielectric layer and spaced apart from the first conductive trace, and a first solder layer connecting the first conductive trace to the second conductive trace of the printed circuit board and extending the full length of the first conductive trace. The electrical component may also include a third conductive trace over the top of the first dielectric layer and a second dielectric layer over the top of the third conductive trace. The electrical component may also include a second solder layer connecting the first ground layer of the component to a second ground layer positioned on the printed circuit board, and a third ground layer positioned on top of the second dielectric layer. The electrical component may also include a first via spanning through the first dielectric layer and the second dielectric layer to connect the first ground layer to the third ground layer.

In another aspect, an electrical component for a printed circuit board may include a first dielectric layer having a top and a bottom, and a first conductive trace positioned on the bottom of the first dielectric layer. The electrical component may also include a first ground layer positioned on the bottom of the first dielectric layer and spaced apart from the first conductive trace. The electrical component may also include a first solder layer connecting the first conductive trace to the second conductive trace of the printed circuit board and extending the full length of the first conductive trace. The electrical component may also include a third conductive trace over the top of the first dielectric layer. The electrical component may also include a second solder layer connecting the first ground layer of the component to a second ground layer positioned on the printed circuit board. The electrical component may also include a third ground layer positioned on top of the first dielectric layer, the third ground layer being spaced apart from the third conductive trace, and a first via spanning through the first dielectric layer to connect the first ground layer to the third ground layer.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

### BRIEF DESCRIPTION OF THE SEVERAL VIEWS OF THE DRAWING(S)

The present invention will be more fully understood and appreciated by reading the following Detailed Description in conjunction with the accompanying drawings, in which:

FIG. 1 is a cross-sectional view of a broadside coupled coupler assembly in accordance with an embodiment of the present invention;

FIG. 2 is a diagrammatic depiction of the thermal dissipation path for the broadside coupler assembly depicted in FIG. 1;

FIG. 3 is a chart comparing the thermal performance of the broadside coupler assembly of FIG. 1 of the present invention to conventional assemblies;

FIG. 4 is an isometric view of a broadside coupler assembly in accordance with the present invention;

FIG. 5A is a top exploded view of the broadside coupler assembly in accordance with a first embodiment of the present invention;

FIG. 5B is a top exploded view of the broadside coupler assembly in accordance with a second embodiment of the present invention;

FIG. 6 is a bottom exploded view of the broadside coupler assembly in accordance with the present invention;

FIG. 7 is an exploded view of a transmission line assembly in accordance with an embodiment of the present invention;

FIG. 8 is an exploded view of a broadside coupler in accordance with another embodiment of the present invention;

FIG. 9 is a plan view of a broadside coupler assembly in accordance with a further embodiment of the present invention;

FIG. 10 is an exploded view of a thermal bridge in accordance with a further embodiment of the present invention;

FIG. 11 is an exploded view of a thermal bridge in accordance with an embodiment of the invention;

FIG. 12 is an exploded view of a thermal bridge in accordance with an embodiment of the invention;

FIG. 13A is a perspective view of the broadside coupler assembly of FIG. 5B after assembling with arrows A-A illustrating where a cross-section is taken in accordance with an embodiment of the invention;

FIG. 13B is a cross-sectional view of the coupler assembly of FIG. 13A with an internal ground layer between two dielectric layers in accordance with an embodiment of the invention;

FIG. 13C is a cross-sectional view of the coupler assembly of FIG. 13A without any internal ground layer between two dielectric layers in accordance with an embodiment of the invention;

FIG. 14A is a top exploded view of the broadside coupler assembly in accordance with a third embodiment of the present invention;

FIG. 14B is a perspective view of the broad coupler assembly of FIG. 14A after assembling with arrows B-B illustrating where a cross-section is taken in accordance with an embodiment of the invention; and

FIG. 14C is a cross-sectional view of the coupler assembly of FIG. 14B in accordance with an embodiment of the invention.

### DETAILED DESCRIPTION OF THE INVENTION

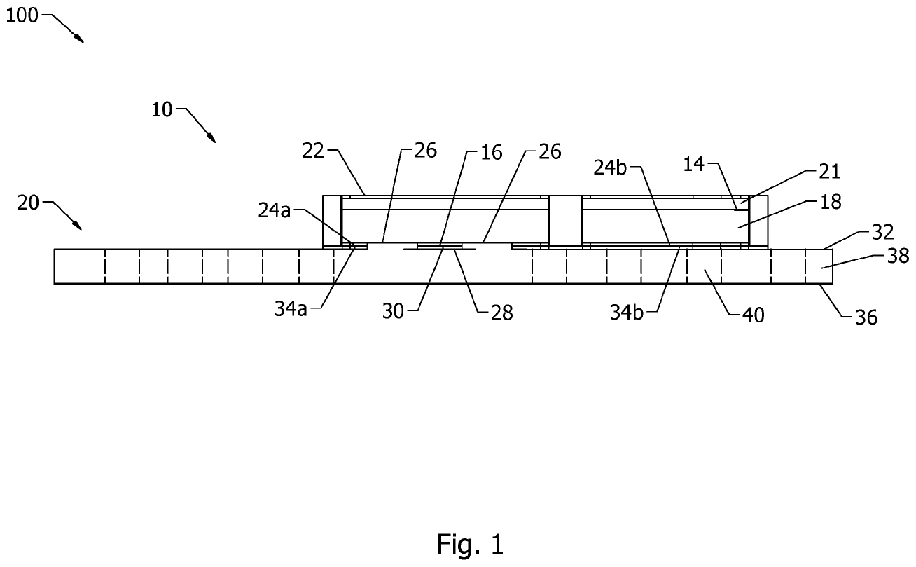

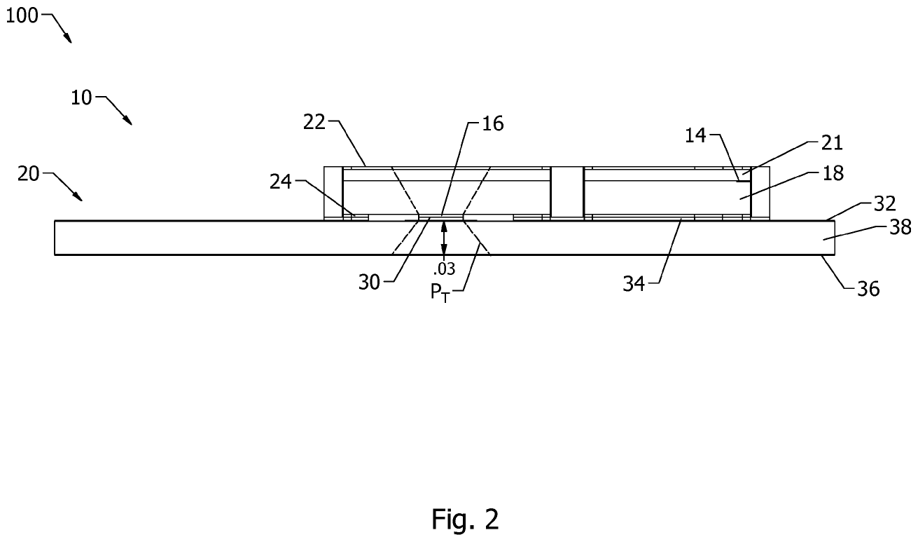

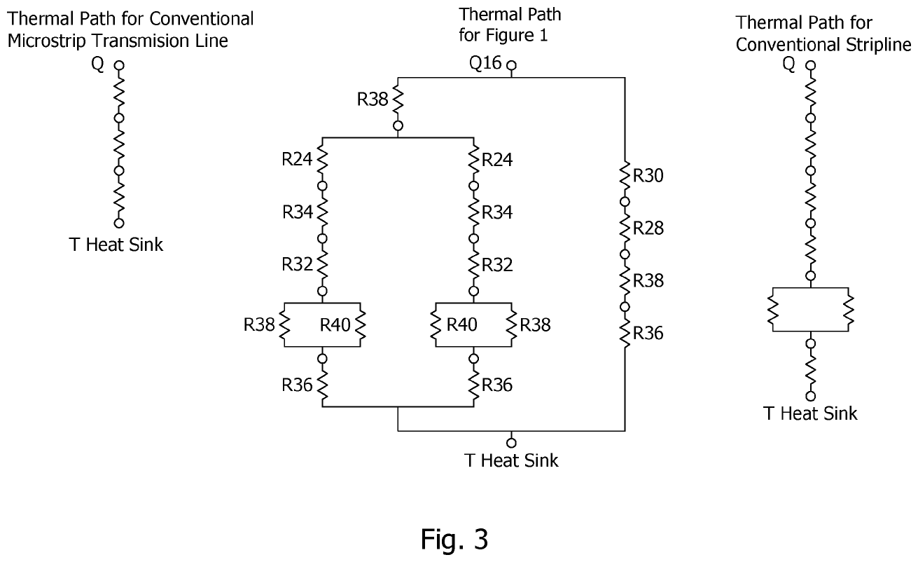

Referring to the figures, wherein like numerals refer to like parts throughout, there is seen in FIG. 1 a cross-sectional view of a broadside coupled coupler assembly 100 having an electrical component 10 configured as a broadside coupler mounted to a printed circuit board (PCB) 20 according to the present invention. Coupler 10 is configured to be adapted to the form factor of PCB 20 to eliminate superfluous thermal resistance layers and improve the thermal dissipation properties and the power handling capabilities of assembly 100. Coupler 10 differs from conventional broadside couplers in that coupler 10 contains approximately “two-thirds” of the typical structure and is instead configured according to the present invention so that PCB 20 provides the remaining structure required to form a complete coupler.

Coupler 10 includes a top conductive trace 14 and a bottom conductive trace 16 disposed on either side of a dielectric layer 18, which may be formed of a material having higher thermal conductivity than a PCB material, such as a ceramic (AlN or Al₂O₃), among others. The dielectric layer 18 with high thermal conductivity may provide a thermal path for removing heat generated from the bottom conductive trace 16. Another dielectric layer 21 is disposed over the top conductive trace 14. Again, the dielectric layer 21 may be formed of a material having high thermal conductivity than a PCB material, such as a ceramic (AlN or Al₂O₃), among others. The dielectric layer 21 with higher thermal conductivity may provide a thermal path for removing heat generated from the top conductive trace 14. A top ground layer 22 is disposed over dielectric layer 21. The heat generated from bottom conductive trace 16 may go up through the dielectric layer 18, dielectric layer 21, to the top ground layer 22. Bottom conductive trace 16 is isolated from a pair of ground layers 24a and 24b by dielectric regions 26 formed therebetween. Coupler 10 is mounted on PCB 20 so that bottom conductive trace 16 is electrically and mechanically coupled to a conductive trace 28 of PCB 20 by a solder layer 30. Bottom ground layers 24a and 24b of coupler 10 are coupled to an upper ground layer 32 positioned on PCB 20 by corresponding layers of solder 34a and 34b. PCB 20 includes another ground layer 36 disposed on the side of a dielectric layer 38 from ground layer 32. PCB 20 may further include interconnection vias 40 formed in the interior of dielectric layer 38 to serve as ground vias or signal vias as needed. The heat generated from the conductive trace 16 may also go down through the solder layer 30, the conductive trace 28, the ground layers 24a and 24b, and the upper ground layer 32 positioned on the PCB 20, and the dielectric layer 38.

As seen in FIG. 2, the thermal dissipation path (PT) for coupler assembly 100 of FIG. 1 extends upwardly through coupler 10 and downwardly through PCB 20. The thermal energy dissipated by a given device or assembly can be expressed as a function of the thermal resistance (Rₜₕ), which is defined by the following equation;

Rₜₕ=D/(k*A),
where k is the Thermal Conductivity of the material that the heat is passing through, D is the Distance of heat flow, and A is the cross-sectional area of the heat flow.

Those skilled in the art will appreciate that the area (A) can be defined as the region under the PCB 20 and substantially within the thermal dissipation path (PT). In other words, those skilled in the art will appreciate that the area does not necessarily correspond to the dashed line pattern of the thermal dissipation path (PT).

Referring to FIG. 3, the thermal path of broadside coupler assembly 100 of FIG. 1 begins with bottom conductive trace 16 and includes the thermal resistance of solder layer 30, the thermal resistance of PCB conductive trace 28, the thermal resistance of dielectric layer 38, and the thermal resistance of ground layer 36. The total thermal resistance of coupler assembly 100 is thus only nominally more than a conventional microstrip transmission line, which has the thermal resistance path also seen in FIG. 3, and significantly less than a conventional stripline component, also seen in FIG. 3. In addition, as further seen in FIG. 3, broadside coupler assembly 100 has an additional, complementary thermal path that only further brings the total thermal conductivity closer to that of a conventional microstrip transmission line, and even more significantly less than a conventional stripline component. Because coupler 10 of the present invention is adapted to use the form factor of PCB 20, superfluous thermal resistance layers have been eliminated so that the thermal path for device 10 of the present invention is nearly identical to the thermal path for a microstrip transmission line and only one additional resistance component, i.e., solder 30. Thus, the present invention represents a significant improvement over a conventional stripline component.

In some embodiments, the thermal path may include the bottom conductive trace 16, the solder layer 30, the dielectric layer 18, the ground layers 24a and 24b, and the ground layer 32 of the PCB, as illustrated in FIG. 1.

The improvement of coupler 10 of the present invention relative to a conventional coupler depicted may be demonstrated using an analysis of standard operating values as follows:
Heat Sink Mounting Interface Temperature=Tmnt=95° C.;
Input Power=Pᵢₙ=100 W;
Insertion Loss=IL=0.05 dB;
Conductor Width=0.025 in;
Conductor Length=0.200 in;
Dielectric Height=0.03 in;
Copper Thickness=0.002 in;
Solder Thickness=0.003 in;
Plated Through Hole Diameter=0.03 in; and
Dielectric Thermal Conductivity=1.25 W/m*K
   Based on the above stated values, the calculations are as follows:

| | Dissi- | | | |
|---|---|---|---|---|
| | pated | Thermal | Temperature | Trace |
| | Power | Resistance | Differential | Temperature |
| Description | (W) | (C./W) | (C.) | (C.) |
| Conventional coupler | 1.8 | 101 | 176 | 271 |
| Coupler 10 | 1.6 | 69 | 109 | 204 |
| Percent Improvement | | 31% | 38% | 25% |

Note that the Dissipated Power for the two components (10, 20) is different due to different Trace Temperatures. The values were calculated using the following expressions:
Dissipated Power=Q=Pin*(1-10^{-IL/10})
Thermal Resistance=R=D/(k*A)
Temperature Differential=dT=Q*R
Trace Temperature=T=dT+Tmnt

For this example calculation, there is a 30 percent or greater reduction in Thermal Resistance and Temperature Differential for assembly 100 of the present invention over a conventional stripline coupler assembly. For the same trace temperature, coupler 10 will have a 40 percent or greater power handling increase (from 100 W to 144 W) over a conventional assembly.

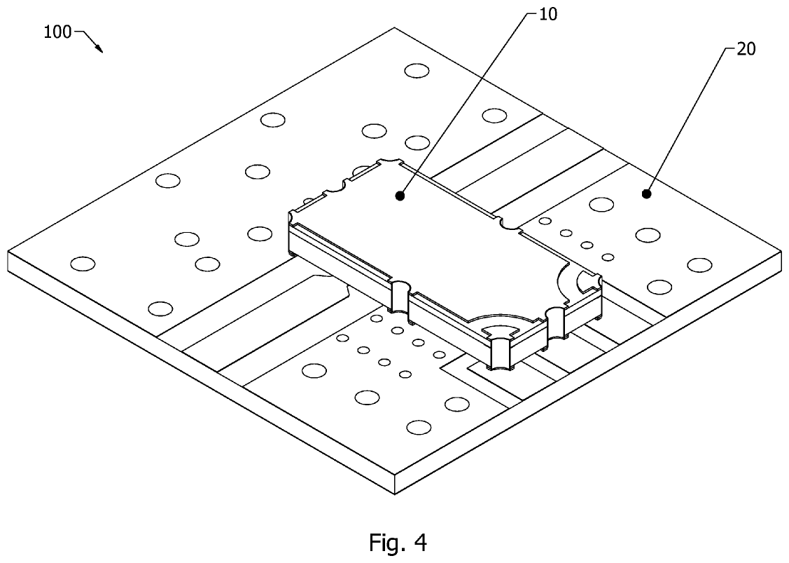

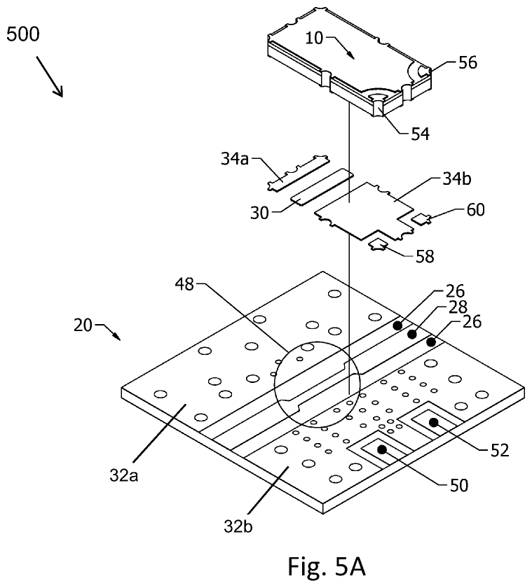

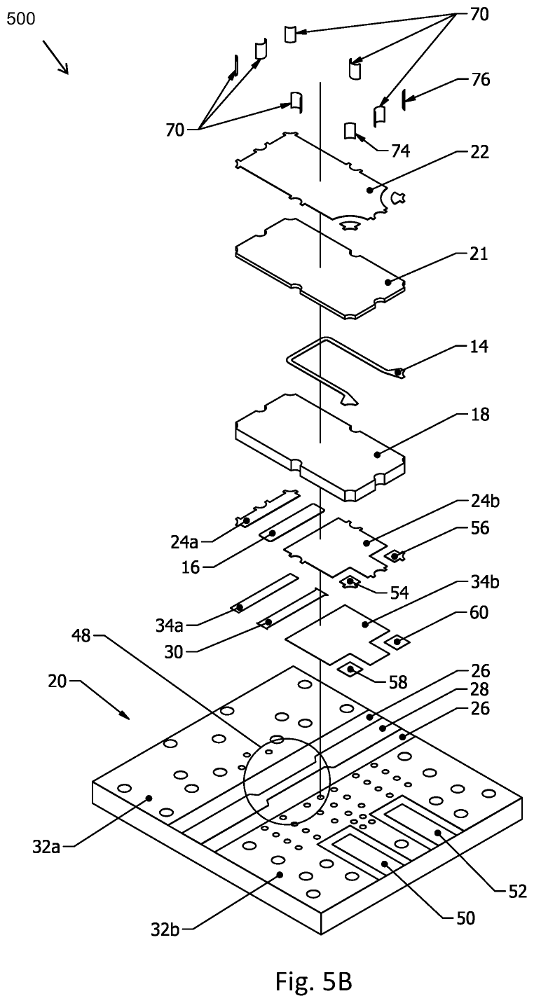

Coupler 10 of FIG. 1 may be used in connection with various applications. For example, as seen in FIG. 4, coupler 10 may be mounted on PCB 20 as described above to form an improved broadside coupled coupler assembly 100. Referring to FIG. 5A, broadside coupler assembly 500 may be formed by disposing coupler 10 over the various requisite solder layers in order to provide the appropriate connections between related portions of coupler 10 and PCB 20. More specifically, a ground layer 32 of PCB 20 has portions removed at predetermined regions to form dielectric regions 26 on either a first ground portion 32a or a second ground portion 32b of microstrip transmission line 28. Note that transmission line 28 is narrower in a region where transmission line 28 overlaps with lower conductive trace or lower coupler trace 16. A solder-connected region 48 provides connectivity with lower coupler trace 16 of coupler 10 via solder layer 30. PCB 20 also includes signal contact regions 50 and 52 that are connected to device pads 54 and 56 via solder pads 58 and 60, respectively. A solder layer 34 couples device ground layer 24 to upper ground layer 32 including the first ground portion 32a and the second ground portion 32b on PCB 20.

Referring to FIG. 5B, vias 74 and 76 are next to ground vias 70. As illustrated, vias 70, 74 and 76 may be castellated vias, and may not complete a full circle. The vias 74 and 76 connect conductive trace 14 to device pads 54 and 56, and also signal contact regions 50 and 52 through solder pads 58 and 60, respectively. Vias 70 connect ground layer 22 to bottom ground layers 24a and 24b, and also connect through solders 34a and 34b to upper ground layer 32, including the first ground portion 32a and the second ground portion 32b positioned on PCB 20. The conductive trace 28 is surrounded by dielectric regions 26. The conductive trace 28 in a circled area 48 has a narrower portion than outer portions outside the circled area 48.

As illustrated in FIG. 5B, the coupler assembly or electrical component 500 may include a first dielectric layer 18 having a top and a bottom, a first conductive trace 16 positioned on the bottom of the first dielectric layer 18, a first ground layer 24a positioned on the bottom of the first dielectric layer 18 and spaced apart from the first conductive trace 16, a second conductive trace 14 positioned on top of the first dielectric layer 18, and a second dielectric layer 21 positioned on top of the second conductive trace 14. A ground layer 22 may be positioned on top of the second dielectric layer 21. This structure may then be attached to a printed circuit board having a third conductive trace 28 that is coupled to the first conductive trace 16 by a first solder layer 30. The printed circuit board 20 may include a third ground layer 32a spaced apart from the third conductive trace 28 and coupled to the first ground layer 24a by a second solder layer 34a. The electrical component 500 may further include at least one interconnection via formed through the first and second dielectric layers 18 and 21. This embodiment may include an RF device where the third conductive trace 28 may include a transmission line and the first conductive trace 16 is wider than the transmission line 28, or the first conductive trace 16 is narrower than the transmission line 28. A set of ground vias 70 may be positioned on either side of the transmission line 28. The printed circuit board 20 may further include signal contact regions 50 and 52 coupled to device pads 54 and 56 associated with the first conductive trace 16.

In some aspects, the electrical component may further include a third dielectric layer supporting a fourth conductive trace and a ground layer positioned on an opposing side of the third dielectric layer from the fourth conductive trace.

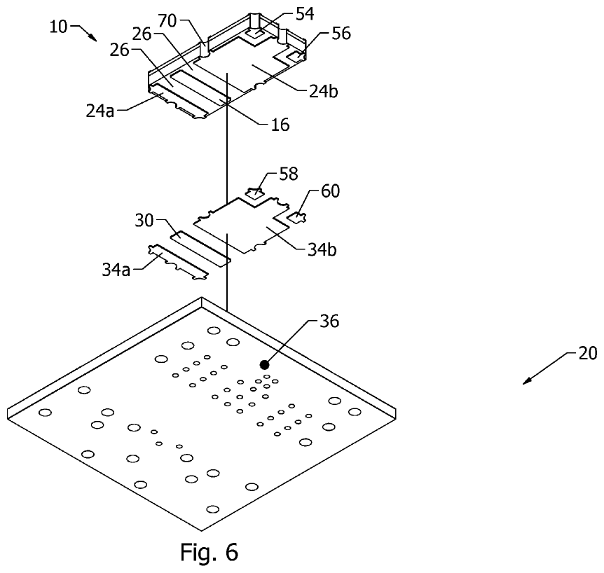

Referring to FIG. 6, solder layer 30 connects to bottom conductive trace 16 on the underside of coupler 10. Signal contact regions 50 and 52 (not visible in this view) are connected to device pads 54 and 56, respectively, via solder pads 58 and 60, respectively. Solder layers 34a and 34b correspond to device ground layers 24a and 24b, respectively. The lower device conductive trace 16 is connected to the microstrip transmission line 28 (not visible in this view) by solder layer 30. Note that device pads 54 and 56 are separated from ground layers 24a and 24b.

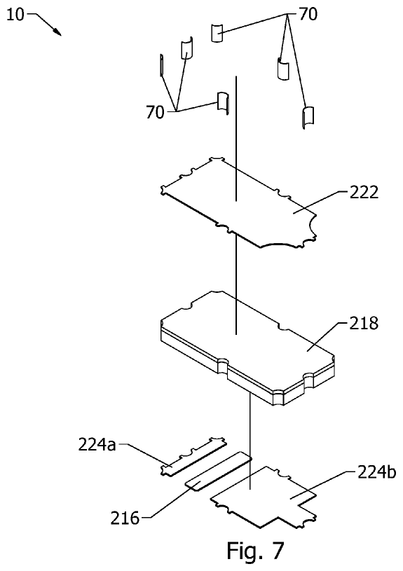

The coupler assembly includes PCB 20 and coupler 10. An exploded view of the coupler 10 is illustrated in FIG. 7. Referring to FIG. 7, component 10 of the present invention may be configured the transmission line assembly 100 in accordance with the present invention includes ground layer 222 disposed over dielectric layer 218. A transmission line conductor 216 is disposed on the opposing side of dielectric layer 218. Transmission line conductor 216 is isolated from device ground layers 224a and 224b as described above with respect to coupler 10. As shown, via 70 spans through dielectric layer 218 above direct trace 216 to connect ground layer 222 above the dielectric layer 218 to ground layer 224a under the dielectric layer 218. Also, the coupler assembly has a thermal path including direct trace 216, dielectric layer 218, ground layer 224a, solder layer 30, and ground layer 32 positioned on the printed circuit board 20.

As shown in FIG. 7, the coupler 10 includes a first dielectric layer 218 having a top and a bottom, a first conductive trace 216 positioned on the bottom of the dielectric layer, and a first ground layer 224a positioned on the bottom of the dielectric layer 218 and spaced apart from the first conductive trace 216. A ground layer 222 may be positioned on the top of the first dielectric layer 218. A second ground layer 224b may be positioned on the bottom of the first dielectric layer 218 and spaced apart from the first conductive trace 216 and the first ground layer 224a. In this embodiment, the coupler may be a thermal bridge where the first dielectric layer 218 has high thermal conductivity and is formed from a ceramic material such as AlN or Al₂O₃.

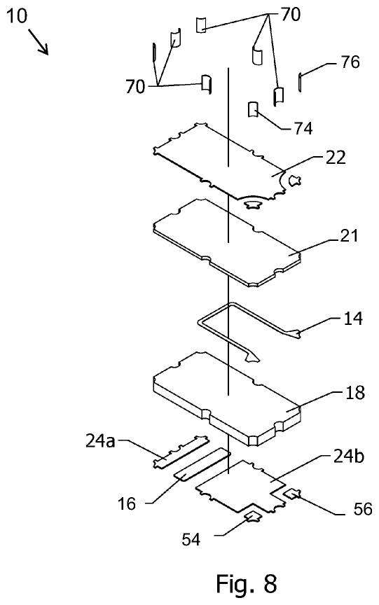

There is seen in FIG. 8 an exploded view of the broadside coupler 10. The top conductive trace 14 is disposed between dielectric layers 18 and 21. A conductive ground layer 22 is disposed over the top of dielectric layer 21. The lower coupler trace or the bottom conductive trace 16 is disposed on the underside of dielectric layer 18. The direct and coupled traces of coupler 10 may be etched on the opposite sides of the dielectric layer 18 to achieve the best layer-to-layer registration as preferred for consistent coupling. The top conductive trace 14 is also referred to as coupled trace 14. The bottom conductive trace 16 is also referred to as coupler trace 16. Coupled trace 14 of coupler 10 is wider than microstrip transmission line 28. Consequently, the coupling is a function of the layer-to-layer alignment of coupler 10 rather than the alignment of coupler 10 to microstrip transmission line 28. Coupler 10 further includes a set of ground vias (PTHs) 70 on either side of the microstrip transmission line that improves both thermal and RF performance. Vias 70 connect ground layer 22 to device ground layers 24a and 24b. Vias 70 also connect ground layer 22 to upper ground layer 32. Also, device pads 54 and 56 are separated from device ground layers 24a and 24b as illustrated in FIG. 8. Coupled trace 14 connects to device pads 54 and 56 by vias (not shown in this view).

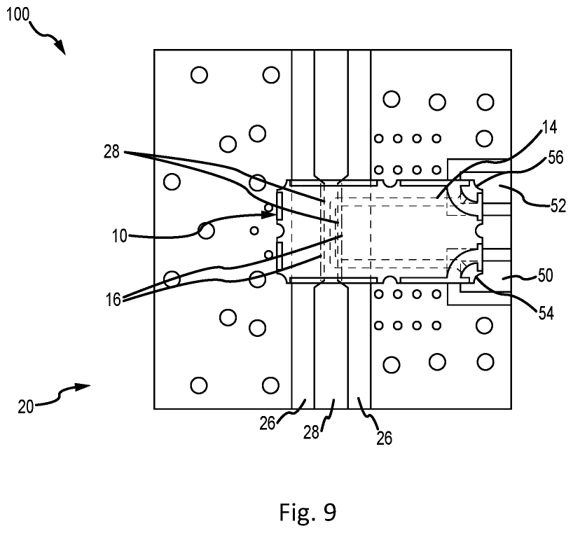

Referring to FIG. 9, a plan view of the broadside coupler assembly 100 illustrates that direct trace 16 of coupler 10 is wider than the microstrip transmission line 28. This view also shows coupled trace 14 (in dash-line) coupled to the signal outputs formed by device pads 54 and 56 and thus signal contact regions 50 and 52. Coupled trace 14 connects to device pads 54 and 56 by vias (not shown in this view) and thus connects to contact regions 50 and 52.

Referring to FIG. 7 again, component 10 of the present invention may be configured for use as a thermal bridge with transmission line conductor 216 being wider than any microstrip transmission line 28, and dielectric layer or core 218 including a material having higher thermal conductivity than a PCB material, such as a ceramic (AlN or Al₂O₃), among others. It will be appreciated by those skilled in the art that any dielectric material with a higher thermal conductivity than the PCB material would be suitable.

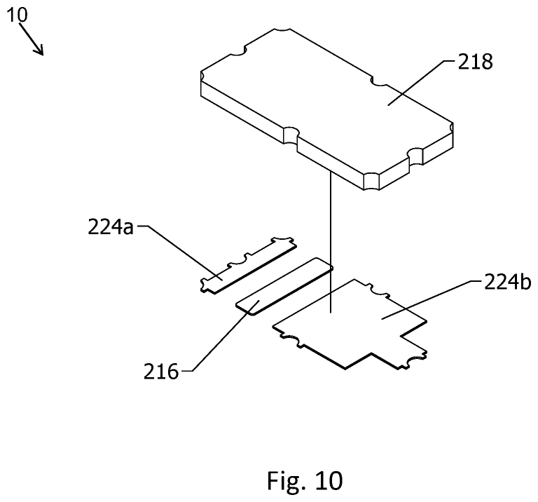

Referring to FIG. 10, ground layer 222 disposed over dielectric layer or core 218 as illustrated in FIG. 7 may be omitted for this implementation, leaving dielectric layer or core 218 as the uppermost surface.

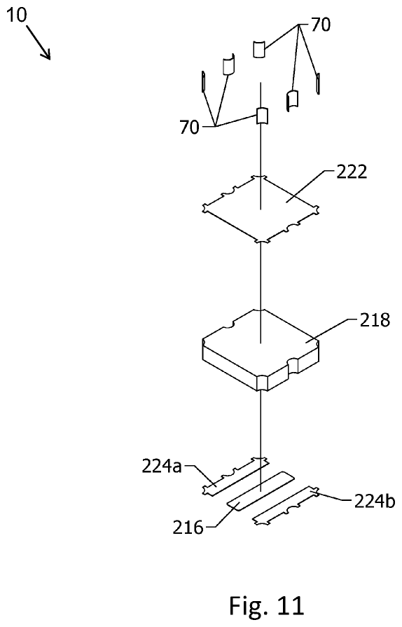

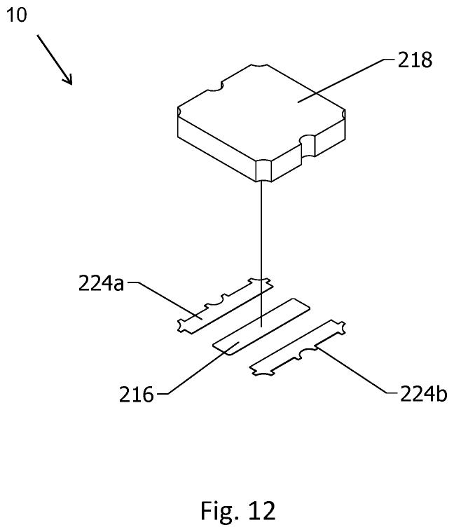

Referring to FIGS. 11 and 12, component 10 may be dimensioned for use as a thermal bridge by reducing the overall length as compared to other embodiments of the invention. As illustrated in FIG. 12, ground layer 222 disposed over dielectric core 218 may be omitted from that illustrated in FIG. 11. Also, dielectric core 218 and ground layer 222 disposed above dielectric core 218 as illustrated in FIGS. 11 and 12 have different shapes from the dielectric layer 18 and ground layer 22, as illustrated in FIGS. 7 and 10. For example, the dielectric layer 18 has a substantially rectangular shape, while the dielectric core 218 has a substantially square shape.

Further, ground layers 224a and 224b as illustrated in FIG. 11 have different patterns or shapes from ground layers 24a and 24b as illustrated in FIGS. 5B, 7-8, and 10. For example, ground layers 224a and 224b have similar patterns, e.g. substantially a strip pattern. In contrast, ground layers 24a and 24b have different patterns, e.g. one having a strip pattern and another one having a non-strip pattern.

Component 10 of the present invention, as illustrated in FIGS. 8-12, may be configured for use as a thermal bridge with transmission line conductor 16 being wider than any microstrip transmission line 28. The dielectric layer or core may include a material having higher thermal conductivity than a PCB material, such as a ceramic (AlN or Al₂O₃), among others. It will be appreciated by those skilled in the art that any dielectric material with a higher thermal conductivity than the PCB material would be suitable.

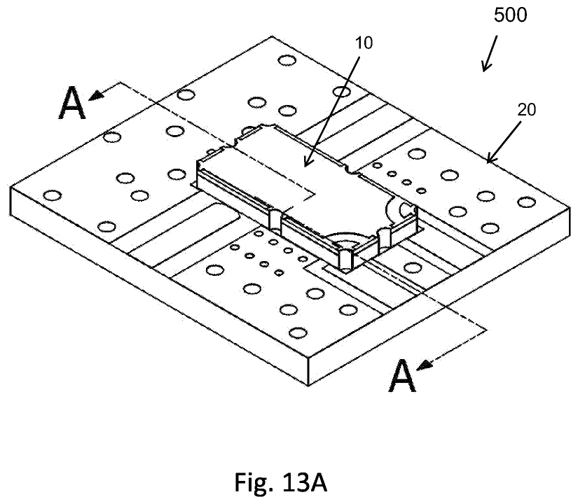

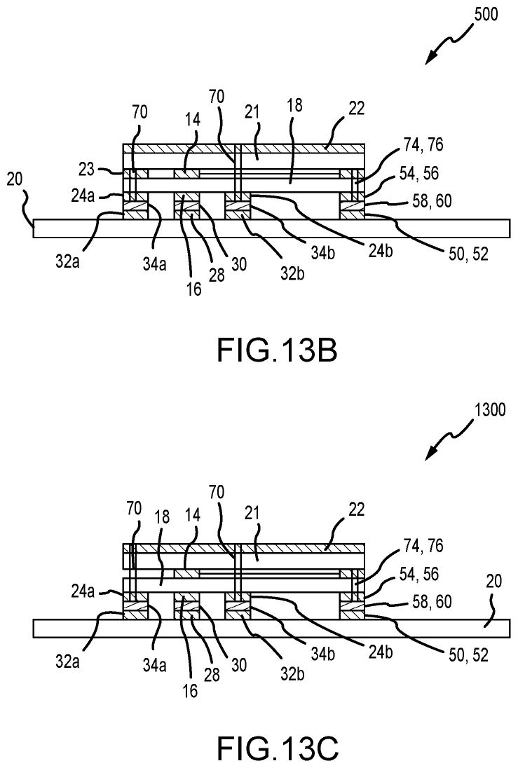

FIG. 13A is a perspective view of the broadside coupler assembly of FIG. 5B after assembling in accordance with an embodiment of the invention. As shown, arrows A-A illustrate where a cross-section is taken. FIG. 13B is a cross-sectional view of the coupler assembly of FIG. 13A with an internal ground layer between two dielectric layers in accordance with an embodiment of the invention.

The coupler assembly or electrical component 500 for a printed circuit board may include a first dielectric layer 18 having a top and a bottom, and a first conductive trace 16 positioned on the bottom of the first dielectric layer 18. The electrical component 500 may also include a first ground layer 24a positioned on the bottom of the first dielectric layer 18 and spaced apart from the first conductive trace 16, which is also referred to a direct trace 16. The electrical component 500 may also include a first solder layer 30 connecting the first conductive trace 16 to a second conductive trace 28 of the printed circuit board 20 and extending the full length of the first conductive trace 16.

The electrical component 500 may also include a third conductive trace 14 over the top of the first dielectric layer 18. The electrical component 500 may also include two or more pads 54 and 56 under the first dielectric layer 18. The two or more pads 54 and 56 are soldered to two or more signal contact regions 50 and 52 of the printed circuit board through solder layers 58 and 60, respectively. The third conductive trace 14 is coupled to signal outputs formed by the two or more signal contact regions 50 and 52 of the printed circuit board 20 through a first via 74 or 76. The electrical component 500 may also include a second solder layer 34a connecting the first ground layer 24a of the component to a second ground layer 32a positioned on the printed circuit board.

In some aspects, the electrical component 500 may also include a thermal path including the first conductive trace 16, the first dielectric layer 18, the first ground layer 24a, the first solder layer 34a, and the second ground layer 32a positioned on the printed circuit board 20. The thermal path may also include ground layer 24b, solder layer 34b, and ground layer 32b positioned on the printed circuit board 20.

In some aspects, the electrical component may also include a third ground layer 23 positioned on the top of the first dielectric layer 18 and a second via 70 spanning the first dielectric layer 18 to connect the third ground layer 23 to the first ground layer 24a.

In some aspects, the electrical component may also include a fourth ground layer 24b positioned on the bottom of the first dielectric layer 18 and spaced apart from the first conductive trace 16 and the first ground layer 24a. The electrical component may also include a fourth solder layer connecting the fourth ground layer 24b of the component to a fifth ground layer 32b of the printed circuit board 20.

In some aspects, the electrical component 500 may also include a second dielectric layer 21 over the third conductive trace 14 and a sixth ground layer 22 positioned on top of the second dielectric layer 21. The electrical component 500 may also include a third via 70 spanning through the first dielectric layer 18 and the second dielectric layer 21 to connect the fourth ground layer 24b to the sixth ground layer 22.

The coupler assembly 500 includes PCB 20 and coupler 10 with an exploded view illustrated in FIG. 5B. As shown in FIG. 13B, the coupled trace 14 extends to the right end and couples to via 74 or 76. Also, via 74 spans through the dielectric layer 18 to connect coupled trace 14 to device pad 54. Similarly, via 76 connects coupled trace 14 to device pad 56. Also, via 70 spans through the dielectric layer 18 under coupled trace 14 from internal ground layer 23 between the top dielectric layer 21 and the bottom dielectric layer 18 to device ground layer 24a under the bottom dielectric layer 18. Further, via 70 connects top ground layer 22 to bottom ground layer 24b through the top dielectric layer 21 and the bottom dielectric layer 18.

As illustrated in FIG. 13B, the internal ground layer 23 is formed in the same conductive layer as the coupled trace 14, but is spaced apart from coupled trace 14 such that the internal ground layer 23 does not interact with the RF field from the coupled trace 14. Also, the conductive trace 16 is in the same conductive layer as the ground layers 24a and 24b and device pads 54 or 56. Further, the ground layers 32a, 32b and second conductive trace 28 are formed in the same conductive layer as the contact regions 50 and 52.

In some aspects, an electrical component 500 for a printed circuit board may include a first dielectric layer 18 having a top and a bottom. The electrical component 500 may also include a first conductive trace 16 positioned on the bottom of the first dielectric layer 18. The electrical component 500 may also include a first ground layer 24a positioned on the bottom of the first dielectric layer 18 and spaced apart from the first conductive trace 16. The electrical component 500 may also include a first solder layer 30 connecting the first conductive trace 16 to the second conductive trace 28 of the printed circuit board 20 and extending the full length of the first conductive trace 16. The electrical component 500 may also include a third conductive trace 14 over the top of the first dielectric layer 18. The electrical component 500 may also include a second dielectric layer 21 over the top of the third conductive trace 14. The electrical component 500 may also include a second solder layer 34a connecting the first ground layer 24a of the component to a second ground layer 32a positioned on the printed circuit board. The electrical component 500 may also include a third ground layer 22 positioned on top of the second dielectric layer 21 and a via 70 spanning through the first dielectric layer 18 and the second dielectric layer 21 to connect the first ground layer 24a to the third ground layer 22.

In some aspects, the electrical component 500 has a thermal path including the first conductive trace 16, the first dielectric layer 18, the first ground layer 24a, the second ground layer 32a positioned on the printed circuit board 20, and the second solder layer 34a. The thermal path may also include the third conductive trace 14, second dielectric layer 21, the third ground layer 22, and the ground layer 23. The thermal path may also include ground layer 24b, solder layer 34b, and ground layer 32b positioned on the printed circuit board 20.

In some aspects, the electrical component 500 has a thermal path including the first conductive trace 16, the first dielectric layer 18, the third conductive trace 14, the second dielectric layer 21, the first ground layer 24a, the second ground layer 32a positioned on the printed circuit board 20, the second solder layer 34a, and the third ground layer 22. The thermal path may also include ground layer 24b, solder layer 34b, and ground layer 32b positioned on the printed circuit board 20.

In some aspects, the first conductive trace is aligned with the second conductive trace on top of the printed circuit board along a full length of the first conductive trace.

FIG. 13C is a cross-sectional view of the coupler assembly of FIG. 13A without any internal ground layer between two dielectric layers in accordance with an embodiment of the invention. As illustrated in FIG. 13C, the internal ground layer 23 of FIG. 13B is not present in FIG. 13C. A coupler assembly 1300 may include a via 70 extending from the ground layer 24a under the bottom dielectric layer 18 through the bottom dielectric layer 18 and the top dielectric layer 21 to the top ground layer 22. The coupler assembly 1300 may include another via 70 spanning from the ground layer 24b under the bottom dielectric layer 18 through the bottom dielectric layer 18 and the top dielectric layer 21 to the top ground layer 22. The coupler assembly 1300 may also include a via 74 or 76 spanning through the bottom dielectric layer 18 to connect the conductive trace 14 above the bottom dielectric layer 18 to the device pad 54 or 56 under the bottom dielectric layer 18.

In some aspects, an electrical component 1300 for a printed circuit board may include a first dielectric layer 18 having a top and a bottom. The electrical component 1300 may also include a first conductive trace 16 positioned on the bottom of the first dielectric layer. The electrical component 1300 may also include a first ground layer 24a positioned on the bottom of the first dielectric layer 18 and spaced apart from the first conductive trace 16. The electrical component 1300 may also include a first solder layer 30 connecting the first conductive trace 16 to the second conductive trace 28 of the printed circuit board and extending the full length of the first conductive trace.

The electrical component 1300 may also include a third conductive trace 14 over the top of the first dielectric layer 18. The electrical component 1300 may also include a second dielectric layer 21 over the top of the third conductive trace 14. The electrical component 1300 may also include a second solder layer 34a connecting the first ground layer 24a of the component to a second ground layer 32a positioned on the printed circuit board.

The electrical component 1300 may also include a third ground layer 22 positioned on top of the second dielectric layer 21. The electrical component 1300 may also include a first via 70 spanning through the first dielectric layer 18 and the second dielectric layer 21 to connect the first ground layer 24a to the third ground layer 22.

In some aspects, the electrical component 1300 has a thermal path including the first conductive trace 16, the first dielectric layer 18, the first ground layer 24a, the first solder layer 34a, and the second ground layer 32a positioned on the printed circuit board 20. The thermal path may also include the third conductive trace 14, the second dielectric layer 21, and the third ground layer 22. The thermal path may also include ground layer 24b, solder layer 34b, and ground layer 32b positioned on the printed circuit board 20.

In some aspects, the first conductive trace is aligned with the second conductive trace on top of the printed circuit board along a full length of the first conductive trace.

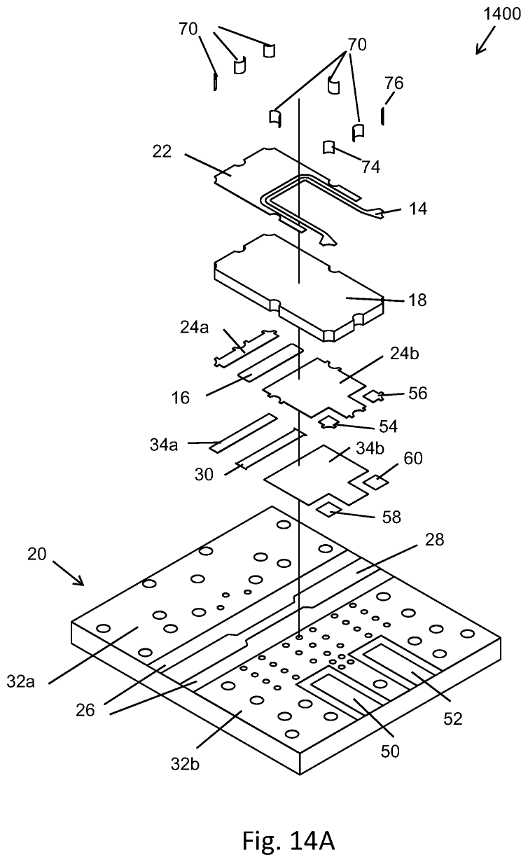

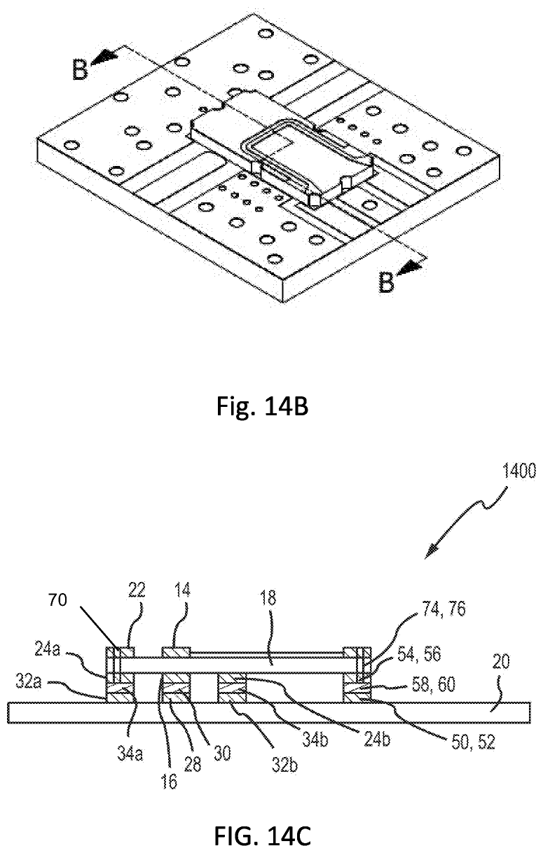

FIG. 14A is a top exploded view of the broadside coupler assembly in accordance with a third embodiment of the present invention. As illustrated, coupler assembly or electric component 1400 is different from the coupler assembly 500 and does not include the dielectric layer 21. The coupler assembly 1400 includes PCB 20 and a coupler. Also, the coupler assembly 1400 includes ground layer 22 and conductive trace 14 in the same conductive layer, but the ground layer 22 is electrically isolated from the conductive trace 14.

FIG. 14B is a perspective view of the broad coupler assembly of FIG. 14A after assembling in accordance with an embodiment of the invention. As illustrated, arrows B-B illustrate where a cross-section is taken. FIG. 14C is a cross-sectional view of the coupler assembly of FIG. 14B in accordance with an embodiment of the invention.

As illustrated in FIG. 14C, in the coupler assembly 1400, via 70 spans through dielectric layer 18 above direct trace 16 to connect the top ground layer 22 above the dielectric layer 18 to ground layer 24a under the dielectric layer 18. The coupled trace 14 extends to the right end and couples to via 74 or 76. Also, via 74 connects coupled trace 14 to device pad 54. Similarly, via 76 connects coupled trace 14 to device pad 56. The top ground layer 22 is in the same conductive layer as the coupled trace 14, but is spaced apart from coupled trace 14 such that the top ground layer 22 does not interact with the RF field from the coupled trace 14.

The coupler assembly 1400 may also include the ground layer 24b positioned on the bottom of the dielectric layer 18 and spaced apart from the conductive trace 16 and the ground layer 24a. The coupler assembly 1400 may also include the solder layer 34b connecting the ground layer 24b of the component to the ground layer 32b on the printed circuit board.

In some aspects, an electrical component 1400 for a printed circuit board may include a first dielectric layer 18 having a top and a bottom and a first conductive trace 16 positioned on the bottom of the first dielectric layer 18. The electrical component 1400 may also include a first ground layer 24a positioned on the bottom of the first dielectric layer 18 and spaced apart from the first conductive trace 16. The electrical component 1400 may also include a first solder layer 30 connecting the first conductive trace 16 to a second conductive trace 28 of the printed circuit board 20 and extending the full length of the first conductive trace 16.

The electrical component 1400 may also include a third conductive trace 14 over the top of the first dielectric layer 18. The third conductive trace 14 is coupled to signal outputs formed by the two or more signal contact regions 50 and 52 of the printed circuit board through a first via 74 or 76. The electrical component 1400 may also include a second solder layer 34a connecting the first ground layer 24a of the component to a second ground layer 32a positioned on the printed circuit board.

The electrical component 1400 may also include a third ground layer 22 positioned on top of the first dielectric layer, the third ground layer 22 being spaced apart from the third conductive trace 14. The electrical component 1400 may also include a first via 70 spanning through the first dielectric layer 18 to connect the first ground layer 24a to the third ground layer 22.

In some aspects, the electrical component 1400 may also include two or more pads 54 and 56 under the first dielectric layer 18. The two or more pads 54 and 56 are soldered to two or more signal contact regions 50 and 52 of the printed circuit board through third solder layers 58 and 60, respectively.

In some aspects, the electrical component 1400 has a thermal path including the first conductive trace 16, the first dielectric layer 18, the first ground layer 24a, the first solder layer 34a, and the second ground layer 32a positioned on the printed circuit board 20. The thermal path may also include ground layer 24b, solder layer 34b, and ground layer 32b positioned on the printed circuit board 20.

In some aspects, the electrical component 1400 may also include a fourth ground layer 24b positioned on the bottom of the first dielectric layer 18 and spaced apart from the first conductive trace 16 and the first ground layer 24a, and a fourth solder layer 34b connecting the fourth ground layer 24b of the component to a fifth ground layer 32b of the printed circuit board 20.

In some aspects, the first conductive trace is aligned with the second conductive trace on top of the printed circuit board along a full length of the first conductive trace.

Having described several embodiments, it will be recognized by those skilled in the art that various modifications, alternative constructions, and equivalents may be used without departing from the spirit of the invention. Additionally, a number of well-known processes and elements have not been described in order to avoid unnecessarily obscuring the invention. Accordingly, the above description should not be taken as limiting the scope of the invention.

Those skilled in the art will appreciate that the presently disclosed embodiments teach by way of example and not by limitation. Therefore, the matter contained in the above description or shown in the accompanying drawings should be interpreted as illustrative and not in a limiting sense. The following claims are intended to cover all generic and specific features described herein, as well as all statements of the scope of the method and system, which, as a matter of language, might be said to fall there between.

What is claimed is:

1. An electrical component for a printed circuit board, comprising:
a first dielectric layer having a top and a bottom;
a first conductive trace positioned on the bottom of the first dielectric layer;
a first ground layer positioned on the bottom of the first dielectric layer and spaced apart from the first conductive trace;
a first solder layer connecting the first conductive trace to a second conductive trace of the printed circuit board and extending the full length of the first conductive trace;
a third conductive trace over the top of the first dielectric layer;
a pad under the first dielectric layer, wherein the pad is soldered to a signal contact region of the printed circuit board, wherein the third conductive trace is coupled to signal outputs formed by the signal contact region of the printed circuit board through a first via; and
a second solder layer connecting the first ground layer of the component to a second ground layer positioned on the printed circuit board.

2. The component of claim 1, wherein the electrical component has a thermal path comprising the first conductive trace, the first dielectric layer, the first ground layer, the first solder layer, and the second ground layer positioned on the printed circuit board.

3. The component of claim 1, further comprising a third ground layer positioned on the top of the first dielectric layer and a second via spanning the first dielectric layer to connect the third ground layer to the first ground layer.

4. The component of claim 3, further comprising a fourth ground layer positioned on the bottom of the first dielectric layer and spaced apart from the first conductive trace and the first ground layer, and a fourth solder layer connecting the fourth ground layer of the component to a fifth ground layer of the printed circuit board.

5. The component of claim 4, further comprising a second dielectric layer over the third conductive trace and a sixth ground layer positioned on top of the second dielectric layer.

6. The component of claim 5, wherein a third via spans through the first dielectric layer and the second dielectric layer to connect the fourth ground layer to the sixth ground layer.

7. The component of claim 1, wherein the second conductive trace comprises a transmission line and is a portion of the electrical component.

8. The component of claim 1, wherein the first dielectric layer is formed from a ceramic material.

9. The component of claim 8, wherein the ceramic material is selected from the group consisting of AlN and Al₂O₃.

10. The component of claim 1, wherein the first conductive trace is wider than the second conductive trace.

11. The component of claim 1, wherein the first conductive trace is narrower than the second conductive trace.

12. The component of claim 1, wherein the first conductive trace is aligned with the second conductive trace on top of the printed circuit board along a full length of the first conductive trace.

13. An electrical component for a printed circuit board, comprising:
a first dielectric layer having a top and a bottom;
a first conductive trace positioned on the bottom of the first dielectric layer;
a first ground layer positioned on the bottom of the first dielectric layer and spaced apart from the first conductive trace;
a first solder layer connecting the first conductive trace to the second conductive trace of the printed circuit board and extending the full length of the first conductive trace;
a third conductive trace over the top of the first dielectric layer;
a second dielectric layer over the top of the third conductive trace;
a second solder layer connecting the first ground layer of the component to a second ground layer positioned on the printed circuit board;
a third ground layer positioned on top of the second dielectric layer; and
a first via spanning through the first dielectric layer and the second dielectric layer to connect the first ground layer to the third ground layer.

14. The component of claim 13, wherein the electrical component has a thermal path comprising the first conductive trace, the first dielectric layer, the first ground layer, the second solder layer, and the second ground layer positioned on the printed circuit board.

15. An electrical component for a printed circuit board, comprising:
a first dielectric layer having a top and a bottom;
a first conductive trace positioned on the bottom of the first dielectric layer;
a first ground layer positioned on the bottom of the first dielectric layer and spaced apart from the first conductive trace;
a first solder layer connecting the first conductive trace to the second conductive trace of the printed circuit board and extending the full length of the first conductive trace;
a third conductive trace over the top of the first dielectric layer;
a second solder layer connecting the first ground layer of the component to a second ground layer positioned on the printed circuit board;
a third ground layer positioned on top of the first dielectric layer, the third ground layer being spaced apart from the third conductive trace; and
a first via spanning through the first dielectric layer to connect the first ground layer to the third ground layer.

16. The component of claim 15, wherein the electrical component has a thermal path comprising the first conductive trace, the first dielectric layer, the first ground layer, the second solder layer, and the second ground layer positioned on the printed circuit board.

17. The component of claim 15, further comprising two or more pads under the first dielectric layer, wherein the two or more pads are soldered to two or more signal contact regions of the printed circuit board.

18. The component of claim 17, wherein the third conductive trace is connected to signal outputs formed by the two or more signal contact regions of the printed circuit board through a second via.

19. The component of claim 15, wherein the third conductive trace comprises a transmission line and is a portion of the electrical component.

20. The component of claim 15, wherein the first dielectric layer is formed from a ceramic material, wherein the ceramic material is selected from the group consisting of AlN and Al₂O₃, wherein the first conductive trace is aligned with the third conductive trace and with the second conductive trace on top of the printed circuit board along a full length of the first conductive trace.
